(19) United States
(12) Patent Application Publication
(10) Pub. No.: US 2025/0344376 A1
(43) Pub. Date: Nov. 6, 2025

(54) METHOD FOR FORMING CONDUCTORS AND THEIR CONTACTS WHICH CARRY SIGNALS FOR ADVANCED SEMICONDUCTOR MEMORY DEVICES

(71) Applicant: Nanya Technology Corporation, New Taipei City (TW)

(72) Inventor: Da-Zen CHUANG, Taipei City (TW)

(73) Assignee: Nanya Technology Corporation, New Taipei City (TW)

(21) Appl. No.: 18/651,931

(22) Filed: May 1, 2024

(51) Int. Cl. H10B 12/00

(52) U.S. Cl. CPC H10B 12/485; H10B 12/02

(57) ABSTRACT

This invention provides a semiconductor structure in which a plurality of first signal-carrying conductor is buried in a first shallow trench isolation structure along a first dimension and underlying active areas of a semiconductor substrate, and a plurality of contact extends from the plurality of first signal-carrying conductor and penetrating through the first shallow trench isolation structure to connect the active areas, a plurality of second signal-carrying conductor is buried in a second shallow trench isolation structure along a second dimension perpendicular to the first dimension and underlying active areas of a semiconductor substrate. The contact may include a conductor pillar integrated with and extending from the first signal-carrying conductor and a conductor stud connecting between the first signal-carrying conductor and the active area. A method for forming the semiconductor structure is also provided.

### BACKGROUND OF THE INVENTION

### Field of the Invention

The present invention relates to the field of semiconductor processing, and more particularly to a method for forming a semiconductor structure to carry signals for advanced semiconductor memory devices.

### Description of the Prior Art

For advanced semiconductor memory IC, such as DRAM, further pushing of geometry has made manufacture of such IC getting extremely difficult. Take DRAM for instance, bit lines are narrow and tall, which makes bit line patterning (both photolithography and etching) hard to immune from pattern wobbling, tilting, and necking. In addition, size of bit-line contacts is too small so that not only patterning of the bit-line contacts is troublesome, but also the integration of the bit line contacts and bit lines is very complicate in order to avoid the electrical short between the bit line contacts and cell contacts, and among bit lines from happening.

Therefore, it is desired to have solution for above mentioned problems.

### SUMMARY OF THE INVENTION

The present invention aims to provide a semiconductor structure for memory cells to ease the integration of bit lines and bit line contacts so that the manufacture of memory, such as DRAM, may be further shrunk and pushed to even smaller geometry.

In one exemplary embodiment, the present invention provides a method for forming conductors and their contacts which carry signals for advanced semiconductor memory device. In this embodiment, a semiconductor substrate is provided and a first dielectric layer is formed on the semiconductor substrate. A plurality of first trench along a first dimension is formed in the semiconductor substrate and a second dielectric layer is formed on the first trenches. A layer of first conductor is formed on the first dielectric layer and the second dielectric layer. A first chemical mechanical polish process is performed to have the first conductor filling the first trenches. Then, a first patterning layer is provided on the first trenches filled with the first conductor to expose some of the first conductor filled in the first trenches to define locations of a plurality of first signal-carrying conductor and contacts of the plurality of the first signal-carrying conductor. Removing part of the exposed first conductor filled in the first trenches to form the plurality of first signal-carrying conductor and first conductor pillars integrated with the plurality of first signal-carrying conductor, wherein the first conductor pillars form part of the contacts of the plurality of first signal-carrying conductor. Then, the first patterning layer is removed. Thereafter, a third dielectric layer is formed on the first trenches so that the plurality of first signal-carrying conductor are buried in the first trenches filled with the third dielectric layer. A second patterning layer is provided on the third dielectric layer and then etching the third dielectric layer to expose the first conductor pillars and locations of active area of the semiconductor substrate for forming first conductor studs, wherein the first conductor pillars and the first conductor studs are served as the contacts of the plurality of first signal-carrying conductor. Then, removing the second patterning layer and forming a layer of the first conductor stud material on the exposed first conductor pillars and the exposed locations of active area of the semiconductor substrate. A second chemical mechanical polish process is performed to form the first conductor studs on the first conductor pillars and the active area of the semiconductor, whereby the plurality of buried first signal-carrying conductor may connect with the active area of the semiconductor substrate via the first conductor pillars and the first conductor studs.

In another exemplary embodiment, after the formation of the plurality of first signal-carrying conductor buried in the first trenches filled with the third dielectric layer. A portion of each of first conductor pillars is removed, and forming a plurality of fourth trench along a second dimension on the semiconductor substrate to define active areas of the semiconductor substrate. Then, a fifth dielectric material fills in the fourth trenches to isolate the active areas of the semiconductor substrate from each other. A fourth patterning layer is provided on the active areas of the semiconductor substrate and then etching the active areas of the semiconductor substrate unprotected by the fourth patterning layer to form a plurality of fifth trench along the second dimension in the active areas of the semiconductor substrate, and then forming a plurality of second signal-carrying conductor buried in the plurality of fifth trench and being covered by a sixth dielectric layer filled in the fifth trench. Then, the fourth patterning layer is removed, and providing a fifth patterning layer and then etching to expose the first conductor pillars and parts of the active areas of the semiconductor substrate. Second conductor studs are formed on the first conductor pillars and the exposed parts of the active areas of the semiconductor substrate such that the second conductor studs and the first conductor pillars form the contacts of the plurality of first signal-carrying conductor.

In one aspect, the present invention provides a semiconductor structure including: a semiconductor substrate having a plurality of active areas on which memory cells occupy formed thereon; a plurality of first shallow trench isolation (STI) along a first dimension formed in the semiconductor substrate; a plurality of second shallow trench isolation along a second dimension perpendicular to the first shallow trench isolation formed in the semiconductor substrate, and the active areas being isolated from each other by the plurality of first shallow trench isolation and the plurality of second shallow trench isolation; a plurality of first signal-carrying conductor along the first dimension underlying the active areas, each of the plurality of first signal-carrying conductor buried in one of the plurality of first shallow trench isolation; a plurality of first contact, each of the plurality of first contact extending from one of the plurality of first signal-carrying conductor and penetrating through the first shallow trench isolation and connecting one of the active areas; and a plurality of second signal-carrying conductor along the second dimension underlying the active areas and buried in the semiconductor substrate.

### BRIEF DESCRIPTION OF THE DRAWINGS

Other objects and advantages of the invention will become apparent upon reading the following detailed description and upon reference to the accompanying drawings in which:

FIG. 1 through FIG. 10 are respective schematic top views of a semiconductor substrate structure at various stages of a method for forming conductors and their contacts which carry signals for advanced semiconductor memory device according to a first embodiment of the present invention;

FIG. 1A through FIG. 9A are schematic cross sectional views along the Y-Y cutting line of FIG. 1 through FIG. 9, respectively;

FIG. 1B through FIG. 9B are schematic cross sectional views along the X-X cutting line of FIG. 1 through FIG. 9, respectively;

FIG. 10B is a schematic cross sectional view along the X-X cutting line of FIG. 10;

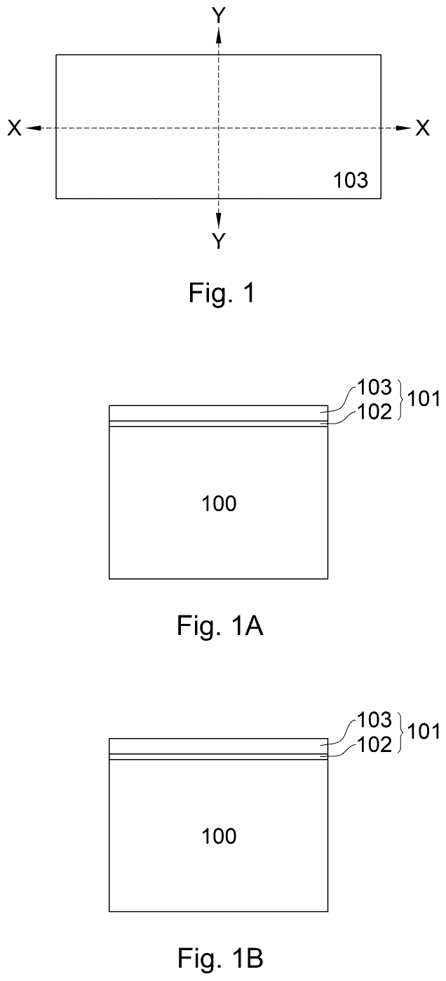

FIG. 1 through FIG. 6 and FIG. 12 through FIG. 19 are respective schematic top views of a semiconductor substrate structure at various stages of a method for forming conductors and their contacts which carry signals for advanced semiconductor memory device according to a second embodiment of the present invention;

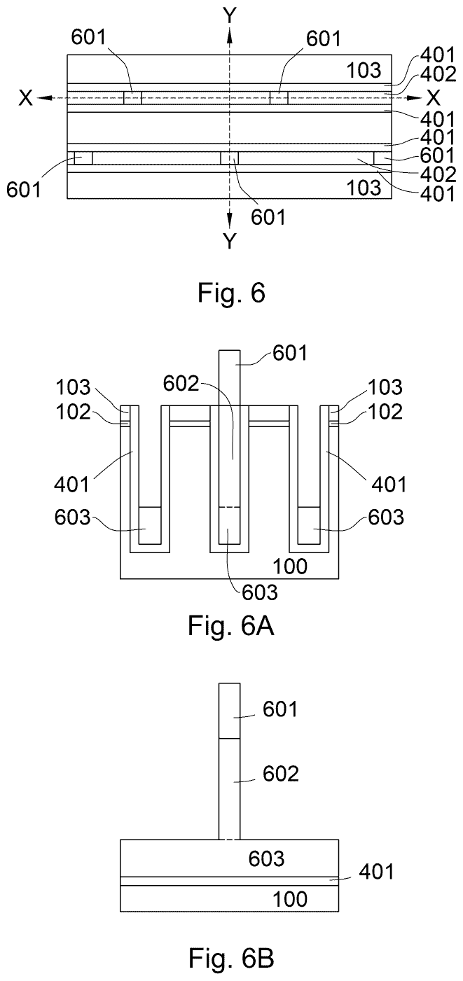

FIG. 11 is a schematic cross sectional view along the Y-Y cutting line of FIG. 6;

FIG. 11A-1 and FIG. 11A-2 are respective schematic cross sectional views along the X-X cutting line of FIG. 6 at different stages of a method for forming conductors and their contacts which carry signals for advanced semiconductor memory device according to the second embodiment of the present invention;

FIG. 13A is a schematic cross sectional view along the X-X cutting line of FIG. 13;

FIG. 14A is a schematic cross sectional view along the X-X cutting line of FIG. 14;

FIG. 15A is a schematic cross sectional view along the X-X cutting line of FIG. 15;

FIG. 16A is a schematic cross sectional view along the X-X cutting line of FIG. 16;

FIG. 17A is a schematic cross sectional view along the X-X cutting line of FIG. 17;

FIG. 18A is a schematic cross sectional view along the X-X cutting line of FIG. 18; and

FIG. 19A is a schematic cross sectional view along the X-X cutting line of FIG. 19.

### DETAILED DESCRIPTION OF THE PREFERRED EMBODIMENTS

The present invention will now be described by way of preferred embodiments with reference to the accompanying drawings. Like numerals refer to corresponding parts of various drawings. Please note well-known circuits, structures and techniques may not be shown in detail in order not to obscure the aspects of the disclosure. Various embodiments will be disclosed herein. However, it is to be understood that the disclosed embodiments are only used as an illustration that can be embodied in various forms. In addition, each of the examples given in connection with the various embodiments are intended to be illustrative but not limiting to. Further, the figures are not necessarily conform to the sizes and dimension ratios of actual structures, and some features are magnified to show details of particular components (and any dimensions, materials, and similar details shown in the figures are intended to be illustrative and not limiting to). Therefore, the particular structural and functional details are disclosed herein are not interpreted as limitations, but are used only to teach those skilled in the relevant field technicians to practice the basis of the disclosed embodiments.

Turning now to the drawings, according to the first embodiment of the present invention, FIG. 1, FIG. 1A and FIG. 1B show a first stage of a method for forming conductors and their contacts which carry signals for advanced semiconductor memory device. FIG. 1 is a schematic top view, FIG. 1A is a schematic cross sectional view along the Y-Y cutting line of FIG. 1 and FIG. 1B is a schematic cross sectional view along the X-X cutting line of FIG. 1.

In the first stage of the method for forming conductors and their contacts which carry signals for advanced semiconductor memory device according to the first embodiment of the present invention, a semiconductor substrate 100 is provided and a first dielectric layer 101 is formed on the semiconductor substrate 100. The semiconductor substrate 100 may be a silicon wafer. The step of forming the first dielectric layer 101 on the semiconductor substrate 100 may further comprises forming a silicon dioxide layer 102 on the semiconductor substrate 100 and forming a silicon nitride layer 103 on the silicon dioxide layer 102.

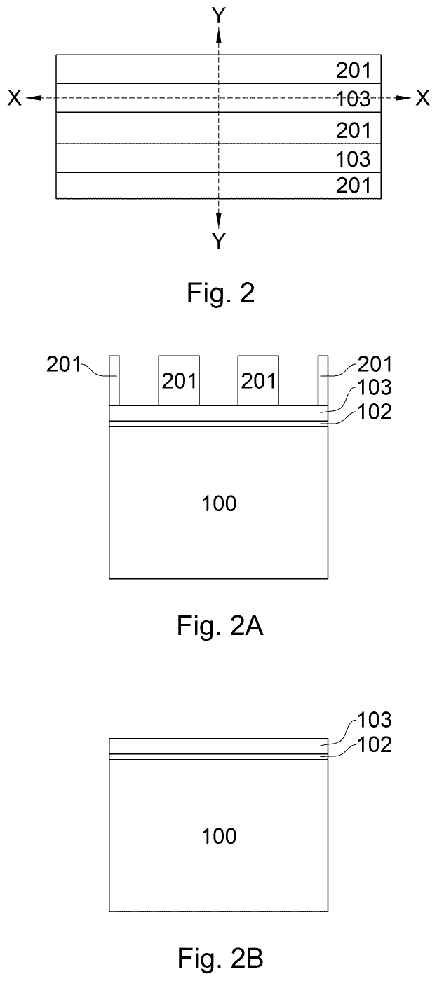

FIG. 2 is a schematic top view of the semiconductor substrate structure at a second stage of the method for forming conductors and their contacts which carry signals for advanced semiconductor memory device according to the first embodiment of the present invention. FIG. 2A is a schematic cross sectional view along the Y-Y cutting line of FIG. 2 and FIG. 2B is a schematic cross sectional view along the X-X cutting line of FIG. 2.

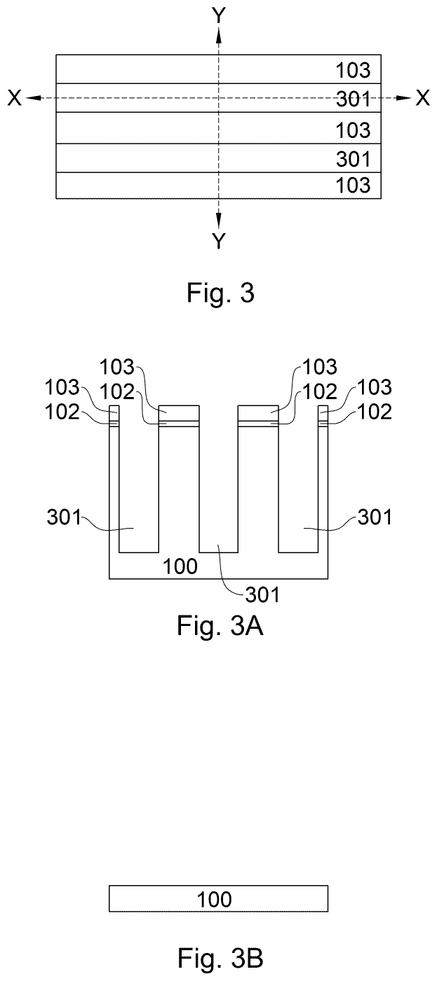

FIG. 3 is a schematic top view of the semiconductor substrate structure at a third stage of the method for forming conductors and their contacts which carry signals for advanced semiconductor memory device according to the first embodiment of the present invention. FIG. 3A is a schematic cross sectional view along the Y-Y cutting line of FIG. 3 and FIG. 3B is a schematic cross sectional view along the X-X cutting line of FIG. 3.

In the second and third stages of the method for forming conductors and their contacts which carry signals for advanced semiconductor memory device according to the first embodiment of the present invention, using a shallow trench isolation (STI) process to form a plurality of first trench 301 along the X direction in the semiconductor substrate 100. As shown in FIG. 2, in the second stage, a patterning photoresist layer 201 is provided on the silicon nitride layer 103. Where the patterning photoresist layer 201 are provided in an interspaced-strips form along the X direction to expose portions of the silicon nitride layer 103 above the semiconductor substrate 100.

Please refer to FIG. 3, FIG. 3A and FIG. 3B, in the third stage of the method for forming conductors and their contacts which carry signals for advanced semiconductor memory device according to the first embodiment of the present invention, the first trenches 301 are formed by etching the silicon nitride layer 103, the silicon dioxide layer 102 and the semiconductor substrate 100 that are photoresist-unprotected. Where the first trenches 301 are inside the semiconductor substrate 100 along the X direction. Then remove the patterning photoresist layer 201.

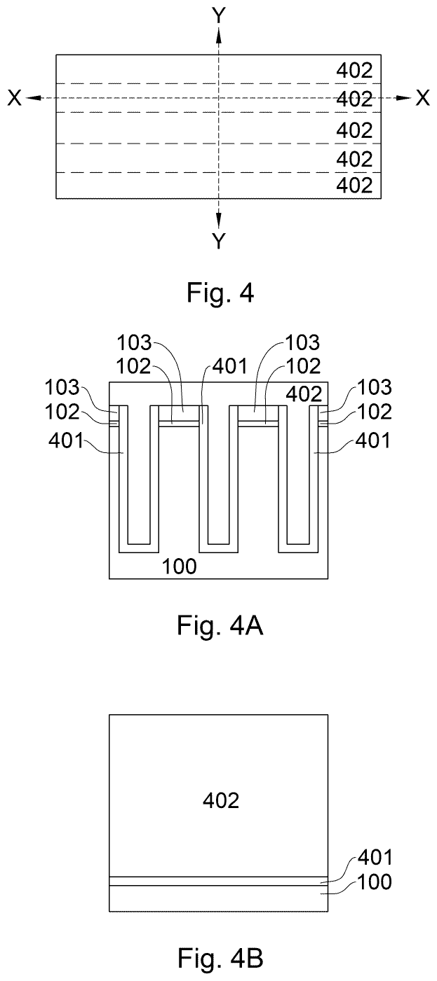

FIG. 4 is a schematic top view of the semiconductor substrate structure at a fourth stage of the method for forming conductors and their contacts which carry signals for advanced semiconductor memory device according to the first embodiment of the present invention. FIG. 4A is a schematic cross sectional view along the Y-Y cutting line of FIG. 4 and FIG. 4B is a schematic cross sectional view along the X-X cutting line of FIG. 4.

In the fourth stage of the method for forming conductors and their contacts which carry signals for advanced semiconductor memory device according to the first embodiment of the present invention, a second dielectric layer 401 for example a silicon dioxide layer is formed along the first trenches 301 and a layer of first conductor 402 is formed on the silicon nitride layer 103 and the second dielectric layer 401 to fill the first trenches 301. Which the first conductor 402 may be made of well-known bit line metal used for the semiconductor memory devices.

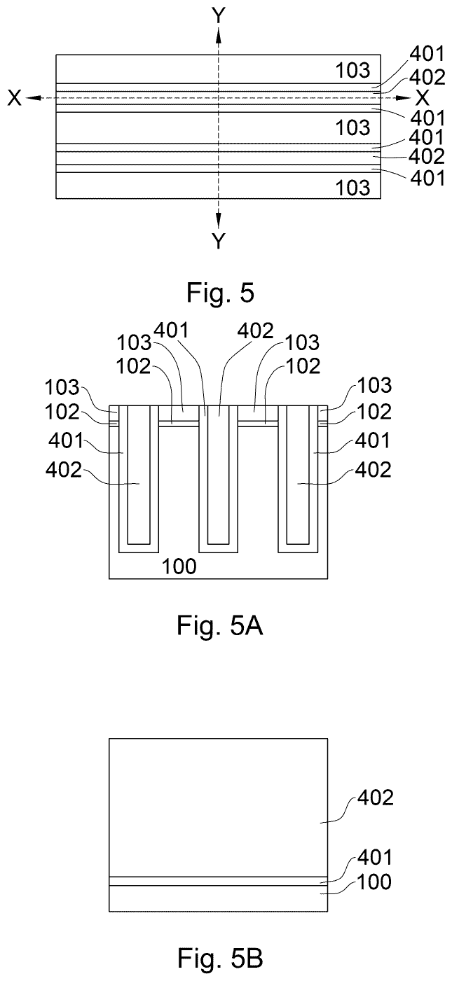

FIG. 5 is a schematic top view of the semiconductor substrate structure at a fifth stage of the method for forming conductors and their contacts which carry signals for advanced semiconductor memory device according to the first embodiment of the present invention. FIG. 5A is a schematic cross sectional view along the Y-Y cutting line of FIG. 5 and FIG. 5B is a schematic cross sectional view along the X-X cutting line of FIG. 5.

In the fifth stage of the method for forming conductors and their contacts which carry signals for advanced semiconductor memory device according to the first embodiment of the present invention, a first chemical mechanical polish process is performed to have the first conductor 402 filling all the first trenches 301.

FIG. 6 is a schematic top view of the semiconductor substrate structure at a sixth stage of the method for forming conductors and their contacts which carry signals for advanced semiconductor memory device according to the first embodiment of the present invention. FIG. 6A is a schematic cross sectional view along the Y-Y cutting line of FIG. 6 and FIG. 6B is a schematic cross sectional view along the X-X cutting line of FIG. 6.

In the sixth stage of the method for forming conductors and their contacts which carry signals for advanced semiconductor memory device according to the first embodiment of the present invention, forming a first patterning layer 601 which is also called BC1 patterning photoresist layer on the first trenches 301 filled with the first conductor 402 to expose some of the first conductor 402 filled in the first trenches 301 to define locations BC1 of a plurality of first signal-carrying conductor and contacts of the plurality of the first signal-carrying conductor. Then, doing timed etch to remove part of the photoresist-unprotected first conductor 402 out of the first trenches 301 and leaving a certain portion of the first conductor 402 on the bottom of the first trenches 301 to form the plurality of first signal-carrying conductor which for example may be as bit lines 603 for memory devices. The part of the first conductor 402 under the photoresist-protected then turns to first conductor pillars 602 integrated with the plurality of first signal-carrying conductor, and the conductor pillars 602 may be as bit line contact pillars.

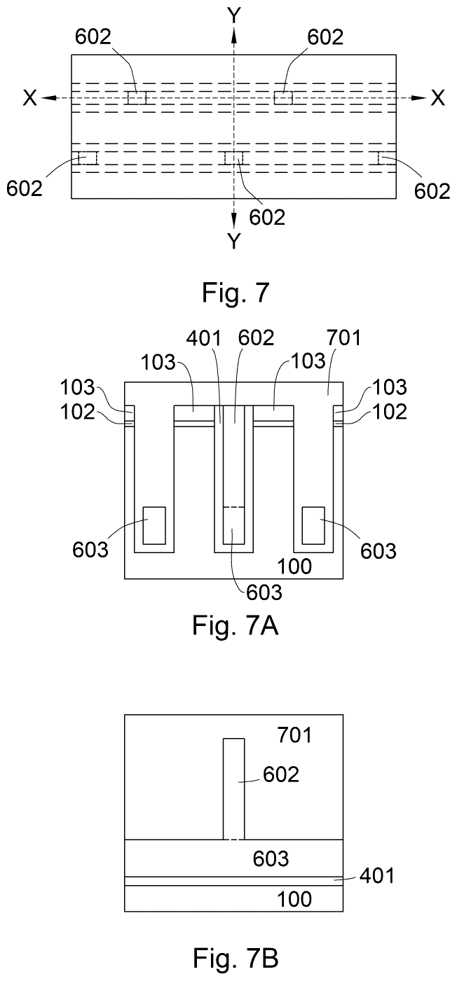

FIG. 7 is a schematic top view of the semiconductor substrate structure at a seventh stage of the method for forming conductors and their contacts which carry signals for advanced semiconductor memory device according to the first embodiment of the present invention. FIG. 7A is a schematic cross sectional view along the Y-Y cutting line of FIG. 7 and FIG. 7B is a schematic cross sectional view along the X-X cutting line of FIG. 7.

In the seventh stage of the method for forming conductors and their contacts which carry signals for advanced semiconductor memory device according to the first embodiment of the present invention, removing the first patterning layer 601 and forming a third dielectric layer 701 for example a silicon dioxide layer on the first trenches 301 so that the plurality of first signal-carrying conductor are buried in the first trenches 301 filled with the third dielectric layer 701. In other words, the bit lines 603 are buried in the first trenches 301, and the first trenches 301 filled with the third dielectric layer 701 may provide a first shallow trench isolation (1st STI) structure. So, by the seventh stage, buried bit lines 603 inside the first shallow trench isolation (1st STI) structure is provided.

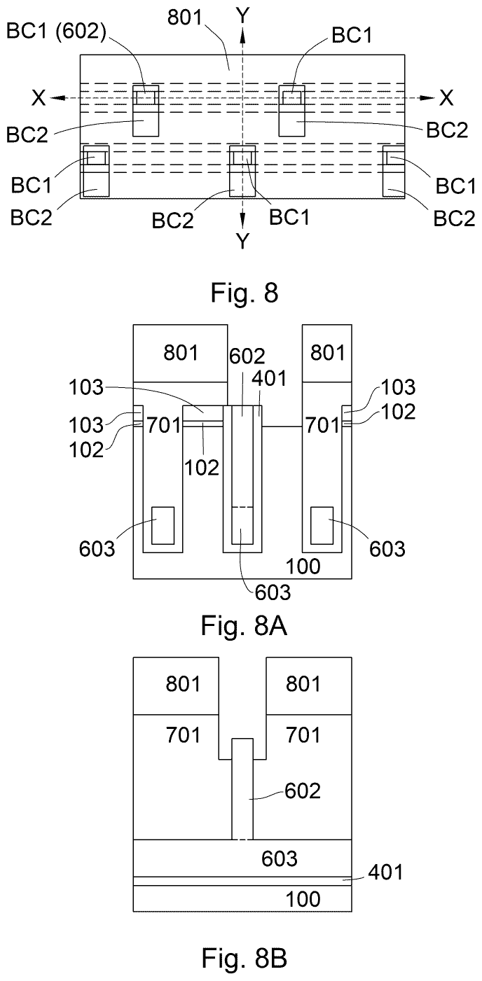

FIG. 8 is a schematic top view of the semiconductor substrate structure at an eighth stage of the method for forming conductors and their contacts which carry signals for advanced semiconductor memory device according to the first embodiment of the present invention. FIG. 8A is a schematic cross sectional view along the Y-Y cutting line of FIG. 8 and FIG. 8B is a schematic cross sectional view along the X-X cutting line of FIG. 8.

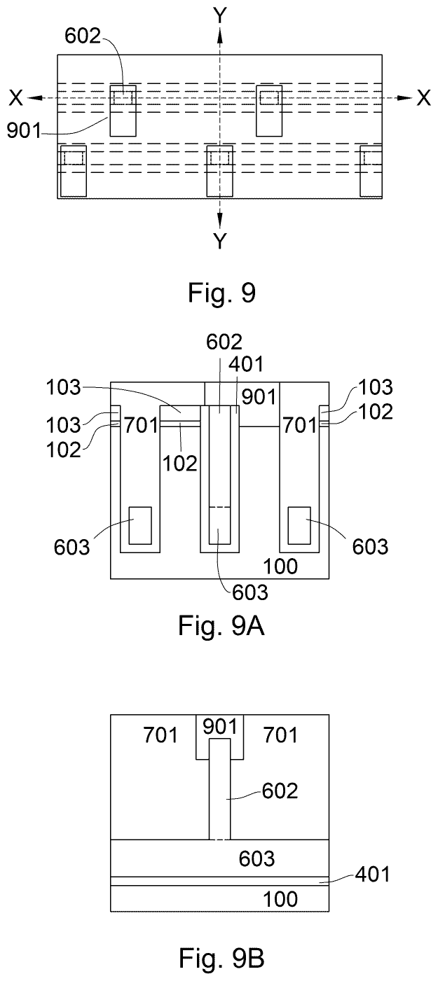

In the eighth stage of the method for forming conductors and their contacts which carry signals for advanced semiconductor memory device according to the first embodiment of the present invention, forming a second patterning layer 801 which is also called BC2 patterning photoresist layer on the third dielectric layer 701 and then etching the photoresist-unprotected third dielectric layer 701 until to expose the first conductor pillars 602 and locations BC2 of active area of the semiconductor substrate 100 for forming the first conductor studs 901 (shown in below FIG. 9), wherein the first conductor pillars 602 and the first conductor studs 901 are served as the contacts of the plurality of first signal-carrying conductor. Namely, the first conductor pillars 602 and the first conductor studs 901 may serve as the contacts of the bit lines 603.

FIG. 9 is a schematic top view of the semiconductor substrate structure at a ninth stage of the method for forming conductors and their contacts which carry signals for advanced semiconductor memory device according to the first embodiment of the present invention. FIG. 9A is a schematic cross sectional view along the Y-Y cutting line of FIG. 9 and FIG. 9B is a schematic cross sectional view along the X-X cutting line of FIG. 9.

In the ninth stage of the method for forming conductors and their contacts which carry signals for advanced semiconductor memory device according to the first embodiment of the present invention, removing the second patterning layer 801 and then forming a layer of the first conductor stud material on the exposed first conductor pillars 602 and the exposed locations BC2 of the active area of the semiconductor substrate 100, and then performing a second chemical mechanical polish process to form the first conductor studs 901 on the first conductor pillars 602 and the active area of the semiconductor substrate 100, whereby the plurality of buried first signal-carrying conductor (bit line 603) may connect with the active area of the semiconductor substrate 100 via the first conductor pillars 602 and the first conductor studs 901.

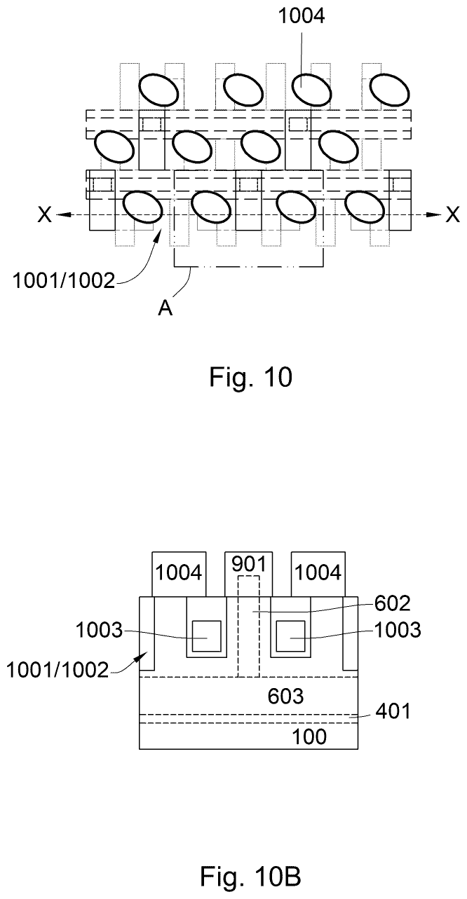

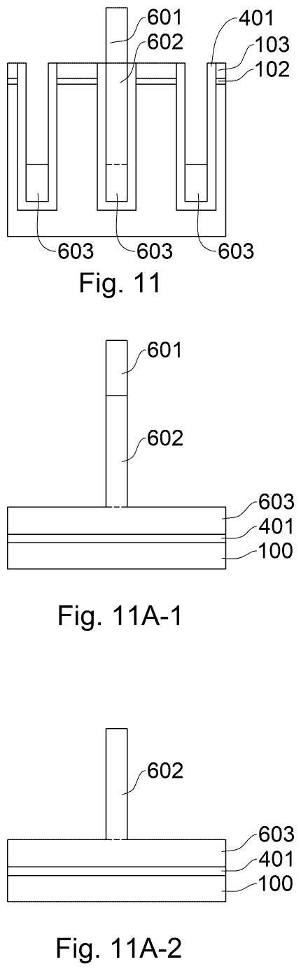

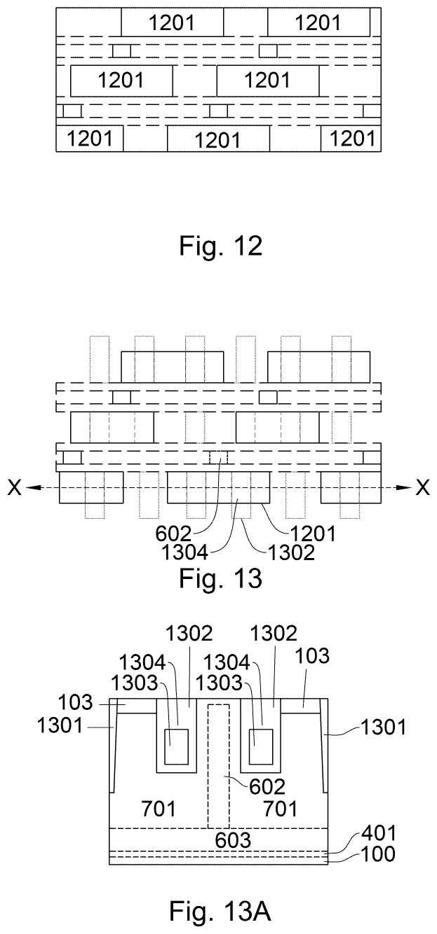

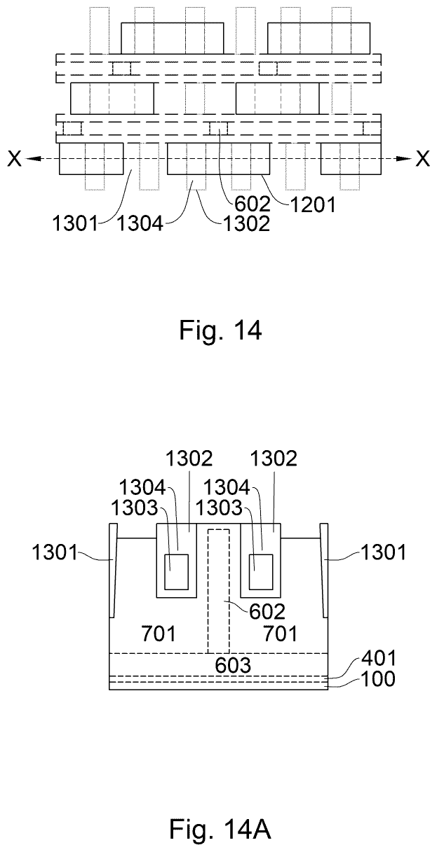

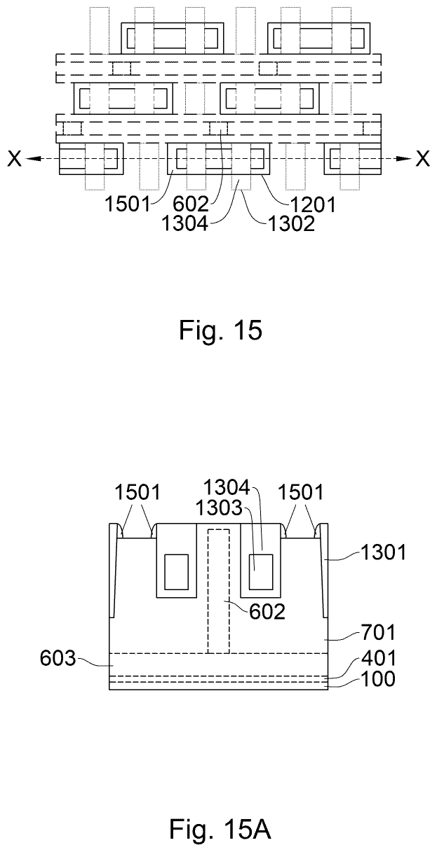

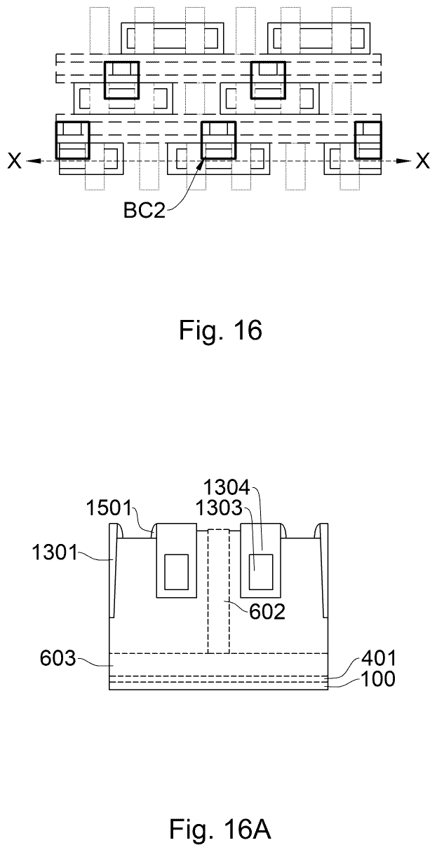

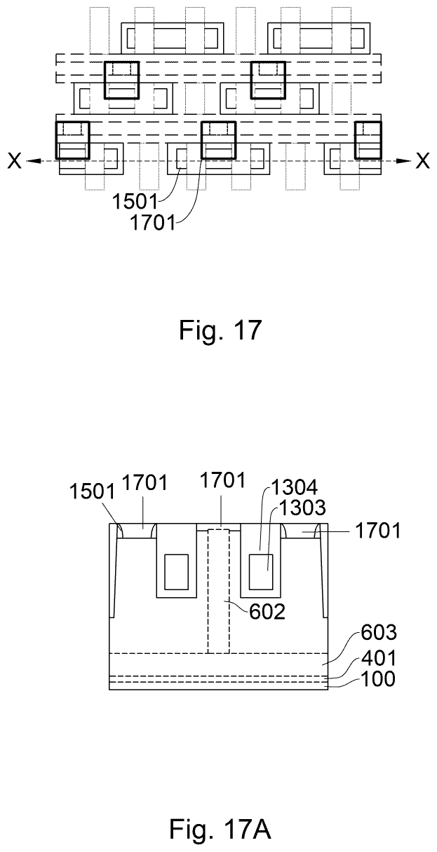

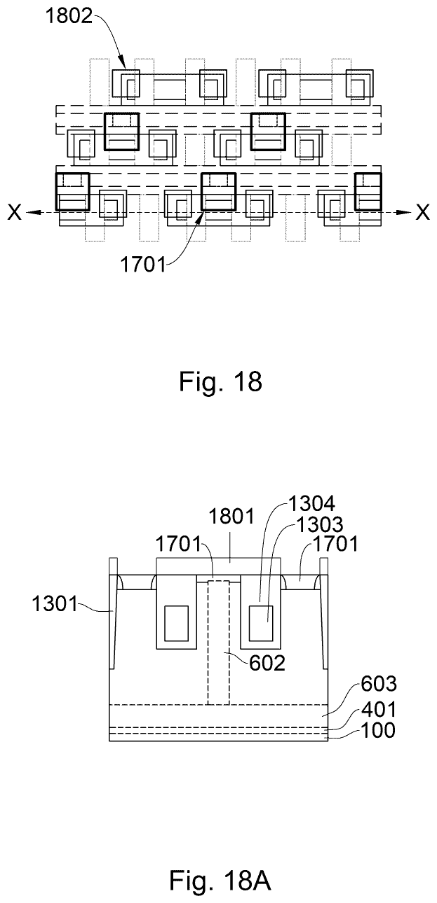

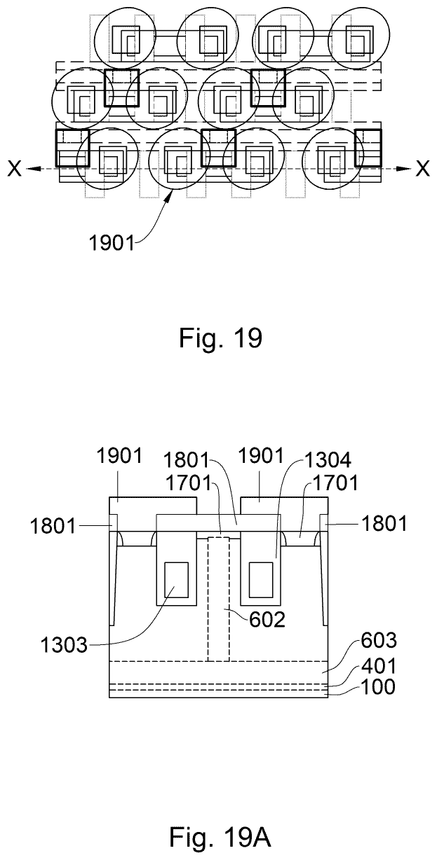

FIG. 10 is a schematic top view of the semiconductor substrate structure at a tenth stage of the method for forming conductors and their contacts which carry signals for advanced semiconductor memory device according to the first embodiment of the present invention. FIG. 10B is a schematic cross sectional view along the X-X cutting line in area A of FIG. 10.

At the tenth stage of the method for forming conductors and their contacts which carry signals for advanced semiconductor memory device according to the first embodiment of the present invention, forming a plurality of second trench 1001 on the semiconductor substrate 100 along the Y direction which is perpendicular to the X direction to separate the active areas of the semiconductor substrate 100 from each other and then filling a fourth dielectric layer 1002 like a silicon dioxide layer in the plurality of second trench 1001. Therefore, a second shallow trench isolation structure (2nd STI) along the Y direction is provided.

According to the process for forming the buried bit lines 603 and their contacts described above, one skilled artisan in the field would appreciate that a plurality of buried word lines 1003 covered by silicon dioxide along the Y direction and a plurality of cell contact 1004 may be formed in the active area of the semiconductor substrate 100. The advanced semiconductor memory device then is ready for following capacitor processing.

In the present invention, the arrangement of the advanced semiconductor memory device (for example, DRAM), such as active area, word line (WL) and bit line (BL), is all square without any pattern going diagonal or in certain angles. This makes photolithography of patterns for advanced memory cells easier.

In the present invention, the manufacture of memory cell STI is done by two steps, one for X direction STI (referred to FIG. 2 to FIG. 3B) and another for Y direction STI (referred to FIG. 10 and FIG. 10B).

In the first embodiment, the bit lines (BL) 603 of memory cells are buried into the semiconductor substrate 100 and placed inside the X-direction STI, so that the bit lines (BL) 603 is self-aligned with the X-direction STI, and there is no need of BL photolithography and etching in the present invention (referred to FIG. 6 to FIG. 6B). Therefore, issues of BL twisting, wobbling, tilting, necking, and shorting to each other or electrical shorting to other patterns in DRAM cells can be resolved completely.

Speaking of bit line contact (BC), in the present invention, it takes two patterns, i.e. the BC1 patterning photoresist layer and the BC2 patterning photoresist layer, to do the job. Connection of BL with BC on DRAM active area is executed via the first conductor studs 901 defined by the BC2 patterning photoresist layer and the first conductor pillars 602 defined by the BC1 patterning photoresist layer (referred to FIG. 8 to FIG. 8B and FIG. 9 to FIG. 9B).

Etching to form the first conductor pillars 602 is done together with the etch back of BL metal, so that the formation of the first signal-carrying conductor (bit line 603) inside the first trench 301 and the first conductor pillars 602 for connecting BL with BC are executed simultaneously (referred to FIG. 5 to FIG. 5B and FIG. 6 to FIG. 6B).

Because there is no need of BL photo mask and BL etch, and the BC pillar is formed together with the BL, the whole process is a lot easier than current DRAM manufacture approach.

Besides, because of bit lines 603 buried inside the first shallow isolation structure, the overlay tolerance of BC to active area in this invention is larger too, which also helps creating more room for cell contacts (CC) to land on active area, and helps improving cell signaling (see FIG. 10 and FIG. 10B).

In addition, additional advantage of this cell structure is that, once buried WL is built, the only areas on wafer not covered with oxide but silicon nitride are BC and CC in each active area island. This makes the reveal of BC and CC to expose silicon easy without the need of complex photolithography steps. For details, please refer to the following second embodiment of the present invention.

For the second embodiment of the present invention, please refer to FIG. 1 through FIG. 6 and FIG. 11 through FIG. 19. The first to sixth stages of the second embodiment of the present invention are same to the first embodiment of the present invention, please refer to above.

Refer to FIG. 11, at the sixth stage of the second embodiment of the present invention, after etching and removing the BC1 patterning photoresist layer (i.e. the first patterning layer 601), performing extra etching to remove a portion of each of the first conductor pillars 602 in order to recess each of the first conductor pillars 602 below the silicon nitride layer 103, see FIG. 11A-1 and FIG. 11A-2.

FIG. 12 is a schematic top view of the semiconductor substrate structure at a seventh stage of the method for forming conductors and their contacts which carry signals for advanced semiconductor memory device according to the second embodiment of the present invention, at seventh stage, forming a plurality of fourth trench 1301 (see below FIG. 13A) along the Y direction on the semiconductor substrate 100 to define active areas (AA) 1201 of the semiconductor substrate 100 and then filling a fifth dielectric material in the fourth trenches 1301 to isolate the active areas 1201 of the semiconductor substrate 100 from each other. Therefore, a second shallow trench isolation structure is provided to define AA islands 1201.

FIG. 13 is a schematic top view of the semiconductor substrate structure at an eighth stage of the method for forming conductors and their contacts which carry signals for advanced semiconductor memory device according to the second embodiment of the present invention, FIG. 13A is a schematic cross sectional view along the X-X cutting line of FIG. 13.

At the eighth stage of the method for forming conductors and their contacts which carry signals for advanced semiconductor memory device according to the second embodiment of the present invention, forming a fourth patterning layer on the active areas 1201 of the semiconductor substrate 100 and then etching the active areas 1201 of the semiconductor substrate 100 unprotected by the fourth patterning layer to form a plurality of fifth trench 1302 along the Y dimension in the active areas 1201 of the semiconductor substrate 100, and then forming a plurality of second signal-carrying conductor 1303 buried in the plurality of fifth trench 1302 and being covered by a sixth dielectric layer 1304 filled in the fifth trench 1302. Wherein the sixth dielectric layer 1304 may be silicon oxide. Wherein the second signal-carrying conductor 1303 is referred as word line (WL).

At the eighth stage, the bit line 603 is buried inside the first shallow trench isolation along the X direction, and the second shallow trench isolation along the Y direction cuts the AA islands 1201, and WL (i.e. the second signal-carrying conductor 1303) is buried inside the fifth trench 1302 and covered with silicon oxide (i.e. the sixth dielectric layer 1304). The only areas on wafer not covered with silicon oxide but silicon nitride are BC and CC in each AA island 1201. This makes the reveal of BC and CC to expose silicon easy without the need of complex photolithography.

FIG. 14 is a schematic top view of the semiconductor substrate structure at a ninth stage of the method for forming conductors and their contacts which carry signals for advanced semiconductor memory device according to the second embodiment of the present invention, FIG. 14A is a schematic cross sectional view along the X-X cutting line of FIG. 14.

At the ninth stage of the method for forming conductors and their contacts which carry signals for advanced semiconductor memory device according to the second embodiment of the present invention, etching the silicon nitride layer 103 with a chemical etch solution having high etching selectivity to silicon dioxide (SiO₂). This reveals silicon surface at BC and CC. Do implantation to BC and CC to form source regions and drain regions for cell transistors.

FIG. 15 is a schematic top view of the semiconductor substrate structure at a tenth stage of the method for forming conductors and their contacts which carry signals for advanced semiconductor memory device according to the second embodiment of the present invention, FIG. 15A is a schematic cross sectional view along the X-X cutting line of FIG. 15.

At the tenth stage of the method for forming conductors and their contacts which carry signals for advanced semiconductor memory device according to the second embodiment of the present invention, performing oxide deposition and etching to make oxide spacer 1501 around the edges of BC and CC.

FIG. 16 is a schematic top view of the semiconductor substrate structure at an eleventh stage of the method for forming conductors and their contacts which carry signals for advanced semiconductor memory device according to the second embodiment of the present invention. FIG. 16A is a schematic cross sectional view along the X-X cutting line of FIG. 16.

At the eleventh stage of the method for forming conductors and their contacts which carry signals for advanced semiconductor memory device according to the second embodiment of the present invention, forming a fifth patterning layer also called BC2 patterning photoresist layer and then etching to expose the first conductor pillars 602 inside the first shallow isolation structure and parts of the active areas of the semiconductor substrate 100.

FIG. 17 is a schematic top view of the semiconductor substrate structure at a twelfth stage of the method for forming conductors and their contacts which carry signals for advanced semiconductor memory device according to the second embodiment of the present invention. FIG. 17A is a schematic cross sectional view along the X-X cutting line of FIG. 17.

At the twelfth stage of the method for forming conductors and their contacts which carry signals for advanced semiconductor memory device according to the second embodiment of the present invention, forming second conductor studs 1701 on the first conductor pillars 602 and the exposed parts of the active areas of the semiconductor substrate 100, whereby the second conductor studs 1701 and the first conductor pillars 602 form the contacts of the plurality of first signal-carrying conductor. The second conductor studs 1701 may be formed by performing blanked polysilicon deposition and followed a chemical mechanical polish process.

At the twelfth stage, it helps connecting the first conductor pillars 602 to second conductor studs 1701 to form the bit line contacts to complete the DRAM data signal path. And if needed, one can add two additional masks to rearrange cell contacts (CC) in a better way for DRAM capacitor processing. Refer to FIG. 18 through FIG. 19A.

FIG. 18 is a schematic top view of the semiconductor substrate structure at a thirteenth stage of the method for forming conductors and their contacts which carry signals for advanced semiconductor memory device according to the second embodiment of the present invention. FIG. 18A is a schematic cross sectional view along the X-X cutting line of FIG. 18. At the thirteenth stage, depositing oxide 1801 and performing CC contact photolithography and etching to define CC contact zone 1802.

FIG. 19 is a schematic top view of the semiconductor substrate structure at a fourteenth stage of the method for forming conductors and their contacts which carry signals for advanced semiconductor memory device according to the second embodiment of the present invention. FIG. 19A is a schematic cross sectional view along the X-X cutting line of FIG. 19. At the fourteenth stage, depositing metal and performing photolithography and etching to form the CC contact 1901.

The present invention also discloses a semiconductor structure which may be manufactured by the method mentioned above and comprises: a semiconductor substrate having a plurality of active areas on which memory cells occupy formed thereon; a plurality of first shallow trench isolation along a first dimension formed in the semiconductor substrate; a plurality of second shallow trench isolation along a second dimension perpendicular to the first shallow trench isolation formed in the semiconductor substrate, wherein the active areas are isolated from each other by the plurality of first shallow trench isolation and the plurality of second shallow trench isolation; a plurality of first signal-carrying conductor along the first dimension underlying the active areas, each of the plurality of first signal-carrying conductor buried in one of the plurality of first shallow trench isolation; a plurality of first contact, each of the plurality of first contact extending from one of the plurality of first signal-carrying conductor and penetrating through the first shallow trench isolation and connecting one of the active areas; and a plurality of second signal-carrying conductor along the second dimension underlying the active areas and buried in the semiconductor substrate. Wherein the first contact includes a conductor pillar and a conductor stud, wherein the conductor pillar is integrated with the first signal-carrying conductor and the conductor stud connects between the conductor pillar and the active area. Wherein the semiconductor substrate is a silicon substrate. Wherein the first signal-carrying conductor is served as a bit line and the second signal-carrying conductor is served as a word line for memory cells.

The above-mentioned embodiments of the present invention are exemplary and not intended to limit the scope of the present invention. Various variation or modifications made without departing from the spirit of the present invention and achieving equivalent effects shall fall within the scope of claims of the present invention.

What is claimed is:

1. A method for forming conductors and their contacts which carry signals for advanced semiconductor memory device, comprising:
providing a semiconductor substrate;
forming a first dielectric layer on the semiconductor substrate;
forming a plurality of first trench along a first dimension in the semiconductor substrate;
forming a second dielectric layer on the first trenches;
forming a layer of first conductor on the first dielectric layer and the second dielectric layer;
performing a first chemical mechanical polish process to have the first conductor filling the first trenches;
forming a first patterning layer on the first trenches filled with the first conductor to expose some of the first conductor filled in the first trenches to define locations of a plurality of first signal-carrying conductor and contacts of the plurality of the first signal-carrying conductor;
removing part of the exposed first conductor filled in the first trenches to form the plurality of first signal-carrying conductor and first conductor pillars integrated with the plurality of first signal-carrying conductor, wherein the first conductor pillars form part of the contacts of the plurality of first signal-carrying conductor; and
removing the first patterning layer.

2. The method of claim 1, further comprising forming a third dielectric layer on the first trenches so that the plurality of first signal-carrying conductor are buried in the first trenches filled with the third dielectric layer.

3. The method of claim 2, further comprising forming a second patterning layer on the third dielectric layer and then etching the third dielectric layer to expose the first conductor pillars and locations of active area of the semiconductor substrate for forming first conductor studs, wherein the first conductor pillars and the first conductor studs are served as the contacts of the plurality of first signal-carrying conductor.

4. The method of claim 3, further comprising removing the second patterning layer and then forming a layer of the first conductor stud material on the exposed first conductor pillars and the exposed locations of active area of the semiconductor substrate, and then performing a second chemical mechanical polish process to form the first conductor studs on the first conductor pillars and the active area of the semiconductor, whereby the plurality of buried first signal-carrying conductor may connect with the active area of the semiconductor substrate via the first conductor pillars and the first conductor studs.

5. The method of claim 4, further comprising forming a plurality of second trench on the semiconductor substrate along a second dimension which is perpendicular to the first dimension to separate the active areas of the semiconductor substrate from each other and then filling a fourth dielectric layer in the plurality of second trench.

6. The method of claim 5, further comprising forming a third patterning layer on the active areas of the semiconductor substrate and then etching the active areas of the semiconductor substrate unprotected by the third patterning layer to form a plurality of third trench along the second dimension in the active areas of the semiconductor substrate, and then forming a plurality of second signal-carrying conductor buried in the plurality of third trench.

7. The method of claim 2, further comprising removing a portion of each of first conductor pillars, and forming a plurality of fourth trench along a second dimension on the semiconductor substrate to define active areas of the semiconductor substrate, and then filling a fifth dielectric material in the fourth trenches to isolate the active areas of the semiconductor substrate from each other.

8. The method of claim 7, further comprising forming a fourth patterning layer on the active areas of the semiconductor substrate and then etching the active areas of the semiconductor substrate unprotected by the fourth patterning layer to form a plurality of fifth trench along the second dimension in the active areas of the semiconductor substrate, and then forming a plurality of second signal-carrying conductor buried in the plurality of fifth trench and being covered by a sixth dielectric layer filled in the fifth trench.

9. The method of claim 8, further comprising removing the fourth patterning layer, and forming a fifth patterning layer and then etching to expose the first conductor pillars and parts of the active areas of the semiconductor substrate, and forming second conductor studs on the first conductor pillars and the exposed parts of the active areas of the semiconductor substrate, whereby the second conductor studs and the first conductor pillars form the contacts of the plurality of first signal-carrying conductor.

10. The method of claim 1, wherein the step of forming the first dielectric layer on the semiconductor substrate comprises forming a silicon dioxide layer on the semiconductor substrate and forming a silicon nitride layer on the silicon dioxide layer.

11. A semiconductor structure, comprising:
a semiconductor substrate having a plurality of active areas on which memory cells occupy formed thereon;
a plurality of first shallow trench isolation along a first dimension formed in the semiconductor substrate;
a plurality of second shallow trench isolation along a second dimension perpendicular to the first shallow trench isolation formed in the semiconductor substrate, wherein the active areas are isolated from each other by the plurality of first shallow trench isolation and the plurality of second shallow trench isolation;
a plurality of first signal-carrying conductor along the first dimension underlying the active areas, each of the plurality of first signal-carrying conductor buried in one of the plurality of first shallow trench isolation;
a plurality of first contact, each of the plurality of first contact extending from one of the plurality of first signal-carrying conductor and penetrating through the first shallow trench isolation and connecting one of the active areas; and
a plurality of second signal-carrying conductor along the second dimension underlying the active areas and buried in the semiconductor substrate.

12. The semiconductor structure of claim 11, wherein the first contact includes a conductor pillar and a conductor stud, wherein the conductor pillar is integrated with the first signal-carrying conductor and the conductor stud connects between the conductor pillar and the active area.

13. The semiconductor structure of claim 11, wherein the semiconductor substrate is a silicon substrate.

14. The semiconductor structure of claim 11, wherein the first signal-carrying conductor is served as a bit line and the second signal-carrying conductor is served as a word line for memory cells.
